(19) United States
(12) Patent Application Publication
(10) Pub. No.: US 2025/0254904 A1
(43) Pub. Date: Aug. 7, 2025

(54) FIELD-EFFECT TRANSISTOR

(71) Applicant: Nippon Telegraph and Telephone Corporation, Tokyo (JP)

(72) Inventors: Taro Sasaki, Tokyo (JP); Takuya Tsutsumi, Tokyo (JP); Hiroki Sugiyama, Tokyo (JP); Fumito Nakajima, Tokyo (JP)

(21) Appl. No.: 18/856,173

(22) PCT Filed: May 24, 2022
(86) PCT No.: PCT/JP2022/021212

§ 371 Date: Oct. 11, 2024

(51) Int. Cl. H10D 30/47

(52) U.S. Cl. CPC H10D 30/4755

(57) ABSTRACT

A field effect transistor of an exemplary embodiment of the present invention includes, on a plane thereof, in order, a source electrode, a first gate electrode, and a drain electrode, and includes in a direction perpendicular to the plane, in order, a first barrier layer, a second gate electrode disposed in the first barrier layer, a first channel layer made of a semiconductor, a second barrier layer which is made of a semiconductor having an energy gap larger than that of the first channel layer and includes an δ-doped layer, a second channel layer made of a semiconductor having an energy gap smaller than that of the second barrier layer, a third barrier layer, and the first gate electrode.

### CROSS-REFERENCE TO RELATED APPLICATIONS

This application is a national phase entry of PCT Application No. PCT/JP2022/021212, filed on May 24, 2022, which application is hereby incorporated herein by reference.

### TECHNICAL FIELD

The present invention relates to a field effect transistor capable of performing a high-output and high-frequency operation.

### BACKGROUND

Since the terahertz frequency band of 0.3 to 3.0 THz is expected to be applied to various applications such as high-speed radio communication of a next generation, non-destructive inspection by imaging using terahertz waves, security applications using transmission image image-capturing, and material analysis using absorption spectra, electronic devices and integrated circuits that can directly handle the terahertz frequency band are attracting attention. In general, field effect transistors made of compound semiconductors with particularly high electron mobility are used as electronic devices with good high-frequency characteristics.

A high-frequency field effect transistor generally has a structure in which a barrier layer including a buffer layer, a channel layer and a carrier supply layer is laminated on a semiconductor substrate, an ohmic cap layer and an ohmic electrode, i.e., source and drain electrodes, are formed on top of the barrier layer, and a gate electrode is formed between the source electrode and the drain electrode.

In this laminated structure, materials and compositions are determined in consideration of a spatial band structure. The carrier supply layer is doped with impurities at a high concentration. Carriers generated by ionization of the impurities are accumulated in a channel layer having a band gap smaller than that of the barrier layer to form a two-dimensional electron gas.

Since the two-dimensional electron gas in the channel layer is spatially separated from the ionized impurities by the barrier layer, the two-dimensional electron gas can travel between the source and the drain at a high speed without being affected by mobility deterioration due to impurity scattering.

In the high-frequency field effect transistor, a voltage is applied to a gate electrode to modulate an energy band structure of the channel layer immediately below the gate electrode, thereby controlling a two-dimensional electron gas concentration in the channel layer, and controlling a current amount flowing between a source and a drain. Therefore, in the case where the source electrode is grounded, an amplified signal can be drawn out from the drain electrode, by inputting the amplified high-frequency signal to the gate electrode.

In particular, when a high-frequency field effect transistor is used to form a circuit such as a power amplifier which is important to increase the output, it is required to take out more outputs from the drain electrode with respect to the high current driving capability of the field effect transistor itself, that is, an input to an arbitrary gate electrode.

As shown in FIGS. 6A and 6B, a general field effect transistor 60 includes a source electrode 603, a gate electrode 604, and a drain electrode 605 on a surface of a channel layer 602 on a substrate 601.

Further, as shown in FIG. 7, in order to improve threshold voltage control and gate controllability in the field effect transistor 70, a structure in which a single channel layer 704 is sandwiched between a front gate 708 and a back gate 703 is disclosed in Japanese Patent No. 6973670 (“NPL 1”). The field effect transistor 70 includes a buffer layer 702 on a substrate 701, and a source electrode 707 and a drain electrode 709 on the surface of a channel layer 704 via ohmic cap layers 705 and 706.

In order to achieve a high current driving capability in such a field effect transistor, a gate electrode width is generally increased.

Further, as shown in FIG. 8, in order to achieve a high current driving capability in the field effect transistor 80, a structure in which each of a source electrode 802, a drain electrode 804, and a gate electrode 803 have a plurality of finger portions formed parallel to each other on an active region (channel layer) 801, and the finger portions are bundled to form one transistor to increase a net gate width (the X-direction in the drawing), a so-called multi-finger structure is disclosed (PTL 1).

### CITATION LIST

### Patent Literature

PTL 1: Japanese Patent No. 6973670

### Non Patent Literature

NPL 1: S. Kodama, T. Furuta, N. Watanabe, H. Ito, A. Kanda, M. Muraguchi and T. Ishibashi, “Variable Threshold AlGaAs/InGaAs Heterostructure Field-Effect Transistors with Paired Gates Fabricated Using the Wafer-Bonding Technique”, Jpn. J. Appl. Phys., vol. 39, Part 1, No. 4B, (2000) pp. 2435-2438.

### SUMMARY

### Technical Problem

However, in a method of improving the current driving capability by simply increasing the gate width, gate resistance occurs in a gate electrode width direction from a gate electrode input end (feed part). In particular, in the case of a high-frequency signal, since the gate resistance is increased by a skin effect or the like, and the input current is attenuated in the gate electrode width direction, the current driving capability is not increased to an expected level.

In a structure in which a single channel layer is sandwiched between two gates of the front gate and the back gate, an improvement of gate controllability is expected, but since only a single channel layer is provided, it is difficult to increase a current driving capability to higher than that of a typical single gate transistor in principle. Therefore, in order to obtain the high driving current, it is necessary to increase the gate electrode width, and an increase in the gate resistance is a problem as described above.

Further, in the multi-finger structure, the propagation of the high-frequency signal becomes more difficult in the finger portion away from the feed part due to the gate resistance, and the current driving capability is not improved to an expected extent.

Further, as the gate width increases, the footprint of the device increases, and the degree of integration decreases. That is, the number of amplifying elements which can be integrated within a specified area is reduced, and an amplifier having a desired output cannot be configured. Even when the circuit area is not specified, since it is necessary to lay the wiring over a long distance in an element having a large footprint, transmission loss is increased and high output is limited.

Further, the increase in the gate resistance deteriorates the high-frequency characteristics. That is, when a high output is achieved by increasing the gate width, the trade-off is achieved with a deterioration in the high-frequency characteristics.

### Solution to Problem

In order to solve the above problem, a field effect transistor according to embodiments of the present invention includes, on a plane, a source electrode; a first gate electrode; and a drain electrode in order, and includes in a direction perpendicular to the plane, in order, a first barrier layer, a second gate electrode disposed in the first barrier layer, a first channel layer made of a semiconductor, a second barrier layer which is made up of a semiconductor having an energy gap larger than that of the first channel layer and includes an δ-doped layer, a second channel layer which is made up of a semiconductor having an energy gap smaller than that of the second barrier layer, a third barrier layer, and the first gate electrode.

### Advantageous Effects of Embodiments of the Invention

According to embodiments of the present invention, a field effect transistor capable of performing a high-output and high-frequency operation can be provided.

### BRIEF DESCRIPTION OF THE DRAWINGS

FIG. 1A is a top schematic diagram showing a configuration of a field effect transistor according to a first embodiment of the present invention.

FIG. 1B is a cross-sectional view taken along line IB-IB′ in FIG. 1A showing the configuration of the field effect transistor according to the first embodiment of the present invention.

FIG. 1C is a cross-sectional view taken along line IC-IC′ in FIG. 1A showing the configuration of the field effect transistor according to the first embodiment of the present invention.

FIG. 2 is a schematic cross-sectional view showing a configuration of a field effect transistor according to a second embodiment of the present invention.

FIG. 3 is a schematic cross-sectional view showing a configuration of a field effect transistor according to a third embodiment of the present invention.

FIG. 4 is a schematic cross-sectional view showing a configuration of a field effect transistor according to a fourth embodiment of the present invention.

FIG. 5 is a schematic cross-sectional view showing a configuration of a field effect transistor according to a fifth embodiment of the present invention.

FIG. 6A is a top schematic diagram showing a configuration of a conventional field effect transistor.

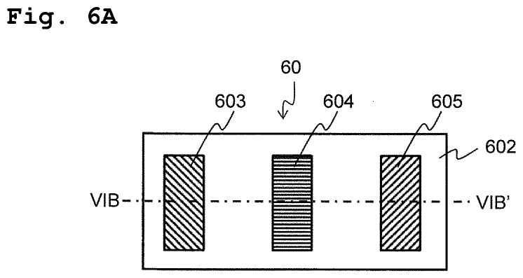

FIG. 6B is a cross-sectional view taken along line VIB-VIB′ in FIG. 6A showing the configuration of the conventional field effect transistor.

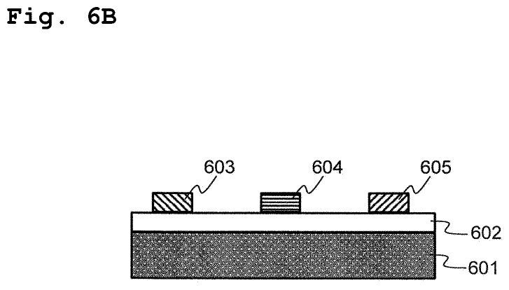

FIG. 7 is a schematic cross-sectional view showing the configuration of a conventional field effect transistor.

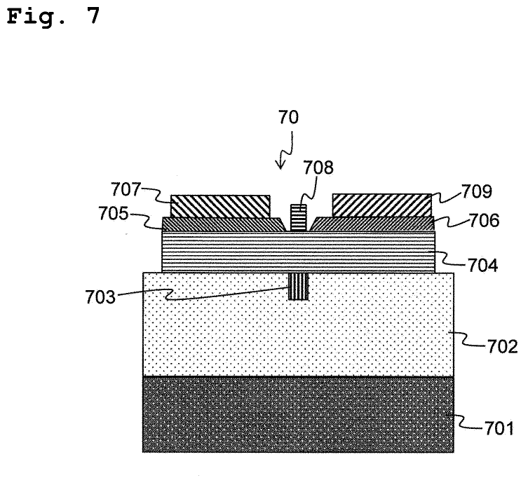

FIG. 8 is a top schematic diagram showing the configuration of a conventional field effect transistor.

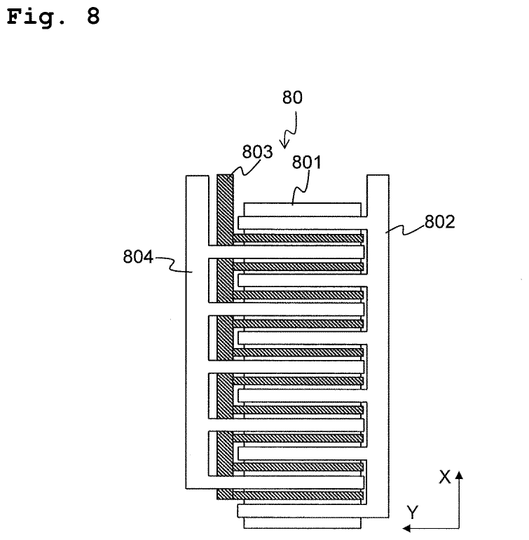

### DETAILED DESCRIPTION OF ILLUSTRATIVE EMBODIMENTS

### First Embodiment

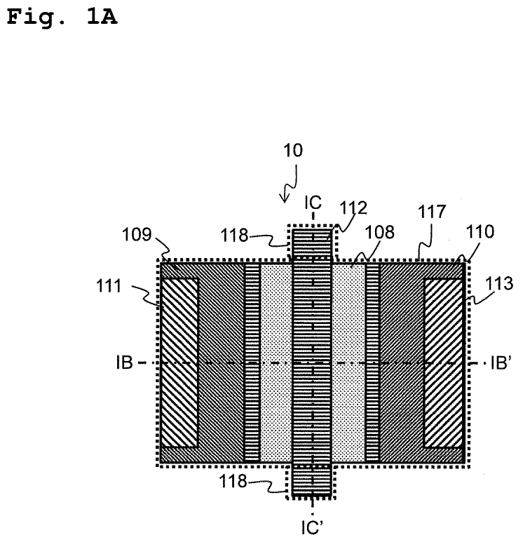

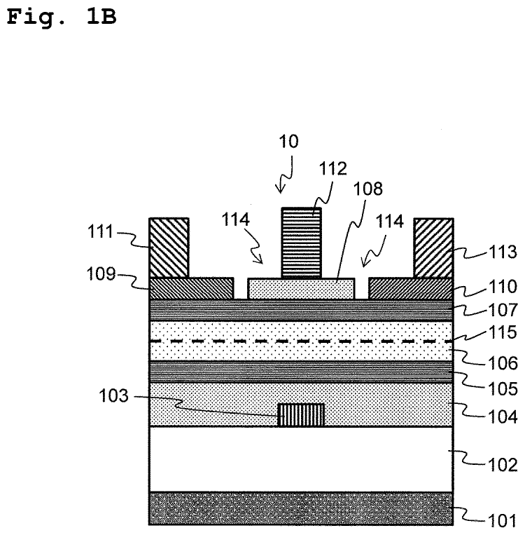

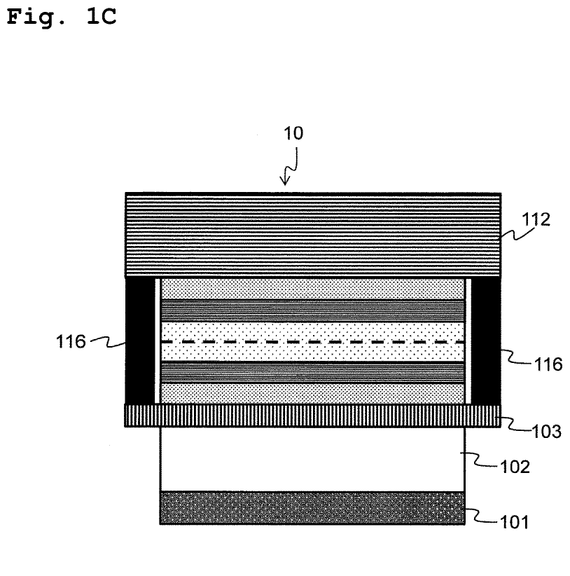

Hereinafter, a field-effect transistor according to a first embodiment of the present invention will be described with reference to FIGS. 1A to 1C.

### Configuration of Field Effect Transistor

In this embodiment, a field effect transistor using InP as a substrate, which is one of the compound semiconductor materials effective for terahertz technology, will be described as an example.

As shown in FIGS. 1A and 1B, a field effect transistor 10 according to the present embodiment includes, in order, a semiconductor (InP) substrate 101, a buffer layer 102, a first barrier layer 104, a first channel layer (hereinafter referred to as a “back gate side channel layer”) 105, a second barrier layer 106, and a second channel layer (hereinafter referred to as a “top gate side channel layer”) 107. Here, a 8-doped layer 115 is provided in the second barrier layer 106.

Here, a second gate electrode (hereinafter also referred to as a “back gate electrode”) 103 is provided in the first barrier layer 104.

Further, a first ohmic cap layer 109 and a source electrode 111 are provided in order at a predetermined position (one position) on a surface (a surface opposite to the second barrier layer 106) of the second channel layer 107, and a second ohmic cap layer 110 and a drain electrode 113 are provided in this order at another position.

Further, a first gate electrode (hereinafter also referred to as “top gate electrode”) 112 is included on the surface of the second channel layer 107, via a third barrier layer 108, between the first ohmic cap layer 109 and the second ohmic cap layer 110, that is, between the source electrode 111 and the drain electrode 113. In this way, the field effect transistor 10 includes, sequentially on its surface, a source electrode 111, a first gate electrode 112, and a drain electrode 113.

The first barrier layer 104 is made of SiO₂ and is formed to cover the back gate electrode 103. The back gate side insulating film 104 may be an oxide or nitride such as SiN, SiON, Al₂O₃, HfO₂, and TiO₂, or a laminated film thereof. Hereinafter, the first barrier layer 104 is also referred to as “back gate side insulating film”.

In the back gate side insulating film 104, a thickness from the surface of the back gate electrode 103 (a surface on the back gate side channel layer 105 side) to the back gate side channel layer 105 is about 1 to 10 nm. This thickness is not limited to this range, and may be set to obtain a desired field effect from the back gate electrode 103 to the back gate side channel layer 105. A thickness obtained by adding a thickness (to be described later) of the second gate electrode (back gate electrode) 103 to this thickness is a total thickness of the back gate side insulating film 104.

The second gate electrode (back gate electrode) 103 has a laminated structure of a metal made up of Ti, Pt and Au, and has a thickness of 100 to 500 nm. Other metals such as Mo may be used.

Alternatively, n-type doped InP, InGaAs, InAlAs or the like may be used for the back gate electrode 103.

The width of the back gate electrode 103 is about 10 to 40 μm.

A length (gate length) of the back gate electrode 103 is about 10 to 200 nm, and corresponds to an operating frequency of about 100 G to 300 G. The gate length of the back gate electrode 103 is not limited to this, and may be set depending on the operating frequency.

Although an example in which the back gate electrode 103 is disposed at an interface between the buffer layer 102 and the back gate side insulating film 104 is shown, the embodiments of the present invention are not limited thereto, but the back gate electrode 103 may be disposed within the back gate side insulating film 104.

The first channel layer (back gate side channel layer) 105 is InGaAs with a film thickness of 5 to 20 nm. Alternatively, a laminated structure of InGaAs and InAs such as In_{0.53}Ga_{0.47}As/InAs/In_{0.53}Ga_{0.47}As and a semiconductor may be used (H. Sugiyama et al, 2012 International Conference on Indium Phosphide and Related Materials, 2012, pp.245 to 248.). Here, the first channel layer 105 may be a semiconductor which has a smaller energy gap than the second barrier layer 106, and a lattice constant in a range in which crystal quality does not deteriorate (for example, a range in which lattice relaxation is not caused).

The second barrier layer 106 is InAlAs or InP (film thickness: 5 to 20 nm). Here, the second barrier layer 106 may be a semiconductor which has a larger energy gap than the first channel layer 105, and a lattice constant in a range in which crystal quality does not deteriorate (for example, a range in which lattice relaxation is not caused).

The 8-doped layer 115 in the second barrier layer 106 is formed by doping Si in a 1×10¹² to 1×10¹³ cm⁻² sheet shape.

The δ-doped layer 115 supplies two-dimensional electrons to the channel layer, and is doped at a high concentration to reduce access resistance from the ohmic electrodes (source electrode 111 and drain electrode 113) to the back gate side channel layer 105.

Specifically, the conduction band in the second barrier layer 106 is locally lowered by the δ-doped layer 115, and the tunnel probability of the carrier increases. Therefore, the access resistance can be reduced with respect to the back gate electrode side channel layer 105 having a long distance (access distance) from the ohmic electrodes (source electrode 111 and drain electrode 113), and carriers can be injected efficiently.

The δ-doped layer 115 is formed in an intermediate portion of the second barrier layer 106. A formation position of the δ-doped layer 115 is not limited to this, but may be formed depending on the thickness of the second barrier layer 106. For example, the δ-doped layer 115 may be disposed to be close to the back gate side channel layer 105 to efficiently increase the carrier tunnel probability and reduce the access resistance.

The second channel layer (top gate side channel layer) 107 is InGaAs with a film thickness of 5 to 20 nm. Alternatively, a laminated structure of InGaAs and InAs such as In_{0.53}Ga_{0.47}As/InAs/In_{0.53}Ga_{0.47} and a semiconductor may be used. Here, the second channel layer 107 may be a semiconductor which has a smaller energy gap than the second barrier layer 106, and a lattice constant in a range in which a crystal quality does not deteriorate (for example, a range in which lattice relaxation is not caused).

Each of the first ohmic cap layer 109 and the second ohmic cap layer 110 is an n-type InAlAs with a film thickness of 5 to 20 nm, and is disposed on the second channel layer (top gate side channel layer) 107. In addition to the n-type InAlAs, a laminated structure of an n-type InGaAs or InAlAs and InGaAs may be used.

The source electrode 111 and the drain electrode 113 have a laminated structure of a metal made up of Ti, Pt and Au, and form an ohmic contact with the second channel layer 107 via the first ohmic cap layer 109 and the second ohmic cap layer 110, respectively. Other metals such as Mo, Ni, or Al may be used for the source electrode 111 and the drain electrode 113. The thickness of the source electrode 111 and the drain electrode 113 is about 50 to 200 nm.

The third barrier layer 108 is disposed in a recess region (hereinafter also referred to as “cap recess”) 114 between the first ohmic cap layer 109 and the second ohmic cap layer 110, on the second channel layer (top gate side channel layer) 107.

Here, the cap recess 114 is a cavity region in which the ohmic cap layer is not disposed.

The third barrier layer 108 is made of SiO₂ having a film thickness of 1 to 10 nm. The top gate side insulating film 108 may be an oxide or nitride such as SiN, SiON, Al₂O₃, HfO₂, and TiO₂ or a laminated film thereof. Hereinafter, the third barrier layer 108 is also referred to as “top gate side insulating film”.

The first gate electrode (top gate electrode) 112 is disposed directly above the back gate electrode 103, on the third barrier layer 108.

Further, the top gate electrode 112 may not be disposed directly above the back gate electrode 103, or may be disposed to be shifted by about 100 to 150 nm, and may be disposed so that an electric field can be applied to a channel between the source electrode 111 and the drain electrode 113, between the top gate electrode 112 and the back gate electrode 103.

The top gate electrode 112 has a laminated structure of a metal made up of Ti, Pt and Au. Other metals such as Mo may be used. The thickness of the top gate electrode 112 is about 100 to 500 nm.

The width of the top gate electrode 112 is about 10 to 40 μm.

The gate length of the top gate electrode 112 is the same as that of the back gate electrode 103. The gate length of the top gate electrode 112 may be different from that of the back gate electrode 103, or may be about 10 to 200 nm. In this case, the gate length corresponds to an operating frequency of about 100 G to 300 G. The gate length of the top gate electrode 112 is not limited to this, but may be set depending on the operating frequency.

The back gate electrode 103 and the top gate electrode 112 are electrically connected by an inter-electrode connecting part 116 as shown in FIGS. 1A and 1C.

Here, the top gate electrode 112 is disposed so that its end 118 is drawn out to the outside of the operating region of the field effect transistor 10, that is, the region (hereinafter referred to as a “mesa structure of the field effect transistor”) 117 including the channel through which carriers travel.

The back gate electrode 103 has the same shape as the top gate electrode 112, and is disposed immediately below the top gate electrode 112.

The back gate electrode 103 and the top gate electrode 112 are electrically connected by the inter-electrode connecting part 116 at respective ends (feed parts) 118. The inter-electrode connecting part 116 is constituted by filling a conductive material into a through-hole penetrating from the top gate side insulating film 108 to the back gate side insulating film 104 in the vertical direction in the laminated structure. Au, Pt, Ti, Mo, W or the like can be used as the conductive material.

Here, the inter-electrode connecting part 116 may be disposed at both ends of the back gate electrode 103 and the top gate electrode 112, or may be disposed at either end of the back gate electrode 103 or the top gate electrode 112.

A cross-sectional shape of the inter-electrode connecting part 116 is rectangular. Here, the cross-sectional shape of the inter-electrode connecting part 116 may be an elliptical shape, a circular shape, a polygon or the like to reduce parasitic capacitance components.

Further, the back gate electrode 103 may have a shape different from that of the top gate electrode 112, or may not be disposed immediately below the top gate electrode 112. The back gate electrode 103 may be electrically connected to the top gate electrode 112 by the inter-electrode connecting part 116.

The inter-electrode connecting part 116 is disposed not to protrude from both electrodes at a junction part between the back gate electrode 103 and the top gate electrode 112. Here, the inter-electrode connecting part 116 may be disposed to protrude from both electrodes or one of the electrodes at the junction part between the back gate electrode 103 and the top gate electrode 112 for the purpose of reducing the gate resistance.

Thus, the circuit configuration can be simplified, and since a voltage can be applied to the back gate electrode 103 and the top gate electrode 112 at the same time, the control can be easily performed.

Here, the back gate electrode 103 and the top gate electrode 112 may be separately controlled in a configuration in which they are not connected.

### Method for Manufacturing Field Effect Transistor

An example of a method for manufacturing the field effect transistor 10 according to the present embodiment will be described below.

First, a semi-insulating InP substrate is used as a sacrificial substrate, and the buffer layer, the top gate side channel layer 107, the second barrier layer 106 including the δ-doped layer 115, and the back gate side channel layer 105 are crystal-grown on the sacrificial substrate in this order by an organometallic vapor phase growth method or a molecular beam epitaxy method.

Specifically, following the growth of the buffer layer, InGaAs or the like (film thickness: 5 to 20 nm) is crystal-grown as the top gate side channel layer 107.

Next, InAlAs or InP (film thickness: 5 to 20 nm) is crystal-grown as the second barrier layer 106.

Here, the δ-doped layer 115 is formed in the second barrier layer 106. The δ-doped layer 115 is formed by doping Si into a sheet shape by 1×10¹² to 1×10¹³ cm⁻² when the crystal of the second barrier layer 106 is grown.

Next, InGaAs (film thickness: 5 to 20 nm) is crystal-grown as the back gate side channel layer 105.

On the other hand, the buffer layer 102, the back gate electrode 103, and the back gate side insulating film 104 are laminated on the semi-insulating InP substrate 101 for a device.

Specifically, first, the buffer layer 102 of undoped InAlAs or the like is laminated by an organometallic vapor phase growing method or a molecular beam epitaxy method.

Next, when n-type InP, InGaAs or InAlAs is used for the back gate electrode 103, the semiconductor is laminated by an organometallic vapor phase growing method, a molecular beam epitaxy method or the like, and then processed by patterning using lithography and etching to form the back gate electrode 103.

When a laminated structure of metals of Ti, Pt, Au and Mo is used for the back gate electrode 103, the back gate electrode 103 is formed by patterning using lithography, electroplating, electroless plating, vacuum deposition, sputtering, etc.

Next, an oxide or nitride such as SiN, SiO₂, SiON or the like is deposited by sputtering as the back gate side insulating film 104 to cover the back gate electrode 103. Here, the back gate side insulating film 104 is deposited by adding about 1 to 20 nm to the normal film thickness (1 to 10 nm) in consideration of the film thickness removed by chemical mechanical polishing in the next process.

Next, the surface of the back gate side insulating film 104 is planarized by chemical mechanical polishing or the like to stick it to the sacrificial substrate well.

Next, the surface of the back gate side channel layer 105 of the laminated structure on the sacrificial substrate and the surface of the back gate side insulating film 104 of the laminated structure of the semi-insulating InP substrate 101 for the device are stuck to each other to be opposite to each other.

Next, the sacrificial substrate and the buffer layer are removed by chemical mechanical polishing or etching. As a result, a laminated structure from the buffer layer 102 to the top gate side channel layer 107 is formed on the semi-insulating InP substrate 101.

Next, an n-type InAlAs or the like is deposited (crystal-grown) on the top gate side channel layer 107.

Next, the source electrode 111 and the drain electrode 113 are formed on the n-type InAlAs or the like by vapor deposition of a metal such as Ti, Pt, Au or the like and photolithography.

Next, a part of n-type InAlAs or the like between the source electrode 111 and the drain electrode 113 is removed by photolithography and etching to expose the surface of the top gate side channel layer 107, and a cap recess 114 is formed. Thus, the first ohmic cap layer 109 on which the source electrode 111 is disposed, and the second ohmic cap layer 110 on which the drain electrode 113 is disposed are formed.

Next, a top gate side insulating film 108 made of an oxide or nitride (film thickness: 1 to 10 nm) such as SiN, SiO₂, SiON or the like is formed on a part of the top gate side channel layer 107 in the cap recess 114, by sputtering, photolithography processing, etc.

Next, a through-hole penetrating in the vertical direction from the top gate side insulating film 108 to the end (feed part) of the back gate electrode 103 in the back gate side insulating film 104 is formed outside the mesa structure 117 of the field effect transistor 10. Subsequently, a conductive material such as Au is filled in the through-hole to form the inter-electrode connecting part 116. As a result, one end of the inter-electrode connecting part 116 is electrically connected to the end of the back gate electrode 103.

Finally, the top gate electrode 112 is formed directly above the back gate electrode 103, on the top gate side insulating film 108 of the cap recess 114. Here, an end (feed part) 118 of the top gate electrode 112 is disposed at the other end of the inter-electrode connecting part 116 and electrically connected.

### Effects

According to the field effect transistor according to the present embodiment, by providing the channel layer on the back gate side and the top gate side, a high current driving capability can be obtained without increasing the gate width and the gate resistance, and high-frequency characteristics can be improved. Further, a circuit using the field effect transistor can be highly integrated.

### Modified Example of First Embodiment

A field effect transistor according to a modified example of the first embodiment of the present invention will be described below.

The field effect transistor according to the present modified example has the same configuration as that of the first embodiment, and differs in the manufacturing method.

### Method for Manufacturing Field Effect Transistor

A method of manufacturing the field effect transistor according to the present modified example will be described below.

First, the buffer layer (for example, InAlAs) 102 is laminated on the semi-insulating InP substrate 101 for a device, and then the back gate electrode 103 and the back gate side insulating film 104 are formed.

Next, a part of the back gate side insulating film 104 is etched outside the mesa structure 117 of the field effect transistor to form an opening, and the buffer layer 102 is exposed.

Next, the same material as that of the buffer layer 102 (for example, InAlAs) is buried and grown on the exposed buffer layer 102 of the opening.

Next, the back gate side channel layer 105 is grown, using the buried and grown crystal (for example, InAlAs) as a nucleus.

Subsequently, the second barrier layer 106 including the δ-doped layer 115 and the top gate side channel layer 107 are crystal-grown in this order by an organometallic vapor phase growing method, a molecular beam epitaxy method, or the like.

Finally, as in the first embodiment, the first ohmic cap layer 109, the second ohmic cap layer 110, the source electrode 111, the drain electrode 113, the cap recess 114, the top gate side insulating film 108, the inter-electrode connecting part 116, and the top gate electrode 112 are formed.

According to the field-effect transistor according to the present modified example, since a laminated structure from the substrate to the ohmic cap layer can be manufactured by a series of laminating processes without requiring a sticking process, the field-effect transistor can be easily manufactured.

### Second Embodiment

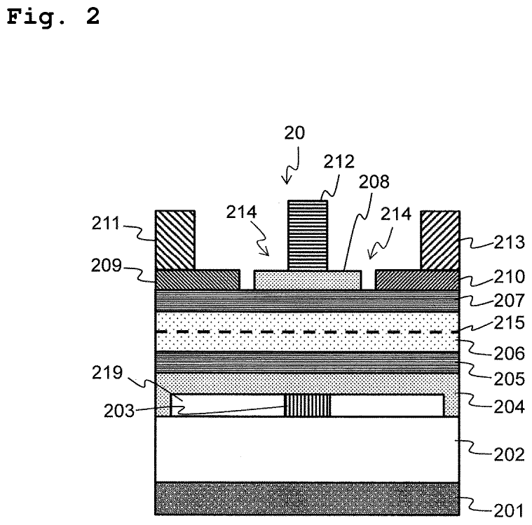

A field effect transistor according to a second embodiment of the present invention will be described with reference to FIG. 2.

### Configuration of Field Effect Transistor

As shown in FIG. 2, a field effect transistor 20 according to the present embodiment has a recess region (region in which the back gate insulating film is not disposed, hereinafter referred to as “back gate side recess”) 219 around a second gate electrode (back gate electrode) 203 in a first barrier layer 204. The other components are the same as in the first embodiment.

### Method for Manufacturing Field Effect Transistor

An example of a method for manufacturing the field effect transistor 20 according to the present embodiment will be described below.

First, the buffer layer 202 is laminated on a substrate (e.g., semi-insulating InP) 201, and then the back gate electrode 203 is formed.

Next, after a photoresist soluble in an organic solvent is applied on the buffer layer 202 to cover the back gate electrode 203, a photoresist pattern is formed as a sacrificial film in a region around the back gate electrode 203 (a region corresponding to the back gate side recess 219) by a lithography process. Here, a thickness of the sacrificial film (photoresist pattern) is equal to or less than the thickness of the back gate electrode 203.

Next, the first barrier layer 204 made up of oxides or nitrides such as SiN, SiO₂, SiON, Al₂O₃-, and HfO₂, and TiO₂, or laminated films thereof is deposited.

Next, as in the first embodiment, a laminated structure of the first channel layer (back gate side channel layer) 205, the second barrier layer 206 including the δ-doped layer 215, and the second channel layer (top gate side channel layer) 207 is formed. Here, the laminated structure may be formed in the same manner as in the first modified example of the first embodiment.

Next, a through-hole reaching the sacrificial film is formed by a lithography process and an etching process at a position that does not affect the device characteristics such as the outside of the mesa structure of the field effect transistor. Subsequently, an organic solvent is injected into the sacrificial film through the through-hole to melt and remove the sacrificial film made of the photoresist.

The length of the back gate side recess 219 is set to 10 to 200 nm similarly to the length of the cap recess (top gate side recess) 214. Here, the length of the back gate side recess 219 may not be the same as the length of the cap recess 214, and may be set by trade-off between the mechanical strength of the laminated structure and the parasitic capacitance reduction effect.

As shown in FIG. 2, the first barrier layer 204 may be left outside the back gate side recess 219.

Finally, as in the first embodiment, a first ohmic cap layer 209, a second ohmic cap layer 210, a source electrode 211, a drain electrode 213, a cap recess 214, a third barrier layer 208, an inter-electrode connecting part (not shown), and a top gate electrode 212 are formed.

According to the field-effect transistor according to the present embodiment, parasitic capacitance components caused by the back gate electrode can be reduced, and high-frequency characteristics can be improved.

### Third Embodiment

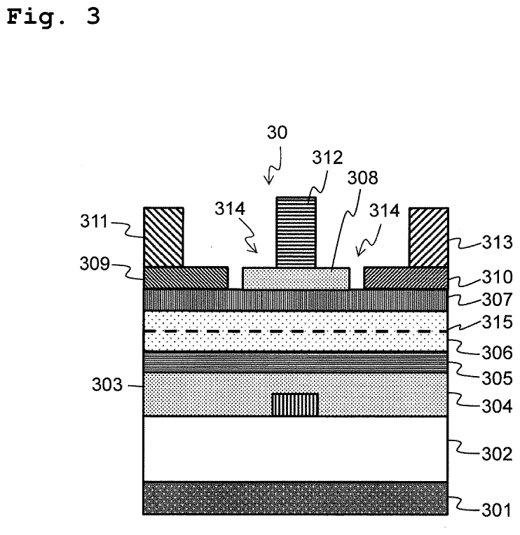

A field effect transistor according to a third embodiment of the present invention will be described with reference to FIG. 3.

### Configuration of Field Effect Transistor

In the field effect transistor 30 according to the present embodiment, as shown in FIG. 3, the second channel layer (top gate side channel layer) 307 and the first channel layer (back gate side channel layer) 305 are made of different materials. The other components are the same as in the first embodiment.

The top gate side channel layer 307 is, for example, In_{0.53}Ga_{0.47}As.

The back gate side channel layer 305 is, for example, a pseudomorphic channel (a channel to which strain is applied due to lattice mismatch) made of In_{0.8}Ga_{0.2}As or InAs.

Thus, since the barrier height is lowered from the top gate side channel layer 307 toward the second barrier layer 306 in the injection of carriers, carrier injection efficiency to the back gate side channel layer 305 is increased, and access resistance can be approximately the same as that of the top gate side channel layer 307.

According to the field effect transistor according to the present embodiment, the current driving capability of the top gate side channel layer and the back gate side channel layer can be made substantially equal, and the current driving capability of the entire field effect transistor can be ideally doubled without increasing the gate width.

Alternatively, the composition of each channel layer can be set to an optimum value so that the mobility of the back gate side channel layer and the top gate side channel layer becomes an appropriate combination depending on a desired high-frequency characteristic, and the high-frequency characteristic can be improved.

Specifically, In_{0.53}Ga_{0.47}As, which is lattice-matched to the InP substrate 301, is used for the top gate side channel layer 307 which has a short distance (access distance) from the ohmic electrodes (source electrode 311, drain electrode 313). On the other hand, In_{0.7}Ga_{0.3}As, In_{0.8}Ga_{0.2}As, or InAs, which have relatively high electron mobility, are used for the back gate side channel layer 305 having a long access distance.

Thus, the delay time of the carrier traveling on the top gate side channel layer 307 and the delay time of the carrier traveling on the back gate side channel layer 305 are made equal to each other, and the carrier delay time difference at the time of the amplification operation is reduced, and the output distortion can be reduced.

Alternatively, by independently optimizing the gate length of the top gate electrode 312 and the gate length of the back gate electrode 303, the delay times in both channels may be equalized.

### Fourth Embodiment

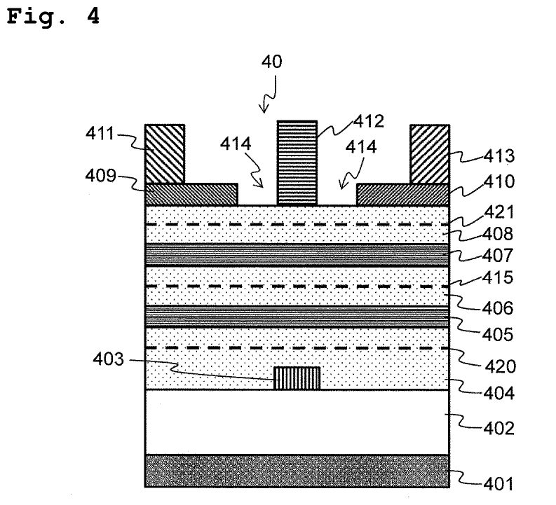

A field effect transistor according to a fourth embodiment of the present invention will be described with reference to FIG. 4.

### Configuration of Field Effect Transistor

As shown in FIG. 4, a field effect transistor 40 according to the present embodiment includes, in order, a semiconductor substrate 401, a buffer layer 402, a first barrier layer 404, a first channel layer (back gate side channel layer) 405, a second barrier layer 406, a second channel layer (top gate side channel layer) 407, and a third barrier layer 408. Here, a δ-doped layer 415 is provided in the second barrier layer 406. A back gate electrode 403 is provided in the first barrier layer 404.

Further, a first ohmic cap layer 409 and a source electrode 411 are provided in order at a predetermined position (one position) on a surface (a surface opposite to the second channel layer 407) of the third barrier layer 408, and a second ohmic cap layer 410 and a drain electrode 413 are provided at another position in this order.

Here, the source electrode 411 and the drain electrode 413 have a laminated structure of a metal made up of Ti, Pt and Au, and form ohmic contacts with the third barrier layer 408 via the first ohmic cap layer 409 and the second ohmic cap layer 410, respectively.

A first gate electrode (top gate electrode) 412 is provided between the first ohmic cap layer 409 and the second ohmic cap layer 410, that is, between the source electrode 411 and the drain electrode 413 on the surface of the third barrier layer 408.

The first barrier layer 404 and the third barrier layer 408 are made of I—InAlAs. A semiconductor such as InP may be used for the first barrier layer 404 and the third barrier layer 408. Hereinafter, the first barrier layer 404 and the third barrier layer 408 are also referred to as “back gate side barrier layer” and “top gate side barrier layer”, respectively. The other components are the same as in the first embodiment.

Here, the first barrier layer 404 may be a semiconductor which has a larger energy gap than the first channel layer 405, and a lattice constant in a range in which crystal quality does not deteriorate (for example, a range in which lattice relaxation is not caused). The third barrier layer 408 may be a semiconductor which has a larger energy gap than that of the second channel layer 407, and a lattice constant in a range in which the crystal quality does not deteriorate (for example, a range in which lattice relaxation is not caused).

Further, δ-doped layers 420 and 421 doped with Si at a high concentration may be formed in the back gate side barrier layer 404 and the top gate side barrier layer 408 to achieve a high current driving capability by increasing the number of carrier supply sources.

The δ-doped layer 415 in the second barrier layer 406 not only supplies carriers to the first channel layer 405 and the second channel layer 407 but also locally lowers the conduction band to increase the tunnel probability of carriers, thereby reducing the access resistance from the ohmic electrodes (the source electrode 411 and the drain electrode 413) to the second channel layer 407.

Similarly, the δ-doped layer 420 in the back gate side barrier layer 404 and the δ-doped layer 421 in the top gate side barrier layer 408 supply carriers to the first channel layer 405 and the second channel layer 407. Here, the δ-doped layer may be formed on either the back gate side barrier layer 404 or the top gate side barrier layer 408, depending on the trade-off between the supply of carriers, the reduction in access resistance, and the process conditions.

For example, in the δ-doped layer 421 in the top gate side barrier layer 408, the reduction in access resistance to the top gate side channel layer 407 can be expected. On the other hand, even if the δ-doped layer 420 is formed in the back gate side barrier layer 404, since the δ-doped layer 420 is located below the back gate side channel layer 405, it is not possible to expect the reduction in the access resistance due to the introduction of the δ-doped layer 420.

Therefore, when carriers are sufficiently supplied from the δ-doped layer 415 in the second barrier layer 406 to the back gate side channel layer 405, the δ-doped layer 420 may not be formed in the back gate side barrier layer 404. Thus, the step of forming the δ-doped layer 420 in the back gate side barrier layer 404 can be omitted, and the manufacturing process can be simplified.

The δ-doped layer 420 in the back gate side barrier layer 404 and the δ-doped layer 421 in the top gate side barrier layer 408 are formed at the center of both barrier layers 404 and 408. Here, the δ-doped layers 420 and 421 may not be formed at the center of the respective barrier layer, and the positions thereof may be determined by trade-off between the carrier supply amount to the channel layer and the reduction in the access resistance.

For example, in the δ-doped layer 421 in the top gate side barrier layer 408, the carrier supply amount to the top gate side channel layer 407 increases as it is closer to the top gate side channel layer 407. On the other hand, the effect of reducing the access resistance is large as it is closer to the ohmic electrodes (the source electrode 411 and the drain electrode 413).

Further, it is possible to obtain a desired carrier supply amount and an access resistance reduction effect, by not only a change in position of the δ-doped layer but also a change in thickness of each barrier layer.

The δ-doped layer 420 in the back gate side barrier layer 404 may be disposed at a position close to the back gate side channel layer 405 to increase the carrier supply amount to the back gate side channel layer 405.

### Method for Manufacturing Field Effect Transistor

An example of a method for manufacturing the field effect transistor 40 according to the present embodiment will be described below.

First, the buffer layer 402 is laminated on the substrate (e.g., semi-insulating InP) 401, and then the back gate electrode 403 is formed.

Next, with the buffer layers 402 on both sides of the back gate electrode 403 as a base, the growth of the back gate side barrier layer 404 made of InAlAs, InP or the like is started, and the back gate electrode 403 is grown until it is completely covered. Here, the δ-doped layer 420 in the back gate side barrier layer 404 is formed after the back gate side barrier layer 404 completely covers the back gate electrode 403.

Next, in order, the back gate side channel layer 405, the second barrier layer 406 including the δ-doped layer 415, the top gate side channel layer 407, and the top gate side barrier layer 408 including the δ-doped layer 421 are crystal-grown by an organometallic vapor phase growth method, a molecular beam epitaxy method, or the like.

Next, an n-type InAlAs or the like is deposited (crystal growth) on the top gate side barrier layer 408.

Next, the source electrode 411 and the drain electrode 413 are formed on the n-type InAlAs or the like by vapor deposition of a metal such as Ti, Pt and Au and photolithography.

Next, a part of n-type InAlAs or the like between the source electrode 411 and the drain electrode 413 is removed by photolithography and etching to expose the surface of the top gate side barrier layer 408, and the cap recess 414 is formed. Thus, the first ohmic cap layer 409 on which the source electrode 411 is disposed, and the second ohmic cap layer 410 on which the drain electrode 413 is disposed are formed.

Next, a through-hole penetrating in the vertical direction from the top gate side barrier layer 408 to the end (feed part) of the back gate electrode 403 of the back gate side barrier layer 404 is formed outside the mesa structure of the field effect transistor 40. Subsequently, a conductive material such as Au is filled in the through-hole to form the inter-electrode connecting part (not shown). As a result, one end of the inter-electrode connecting part is electrically connected to the end of the back gate electrode 403.

Finally, a top gate electrode 412 is formed directly above the back gate electrode 403 on the top gate side barrier layer 408 of the cap recess 414. Here, an end (feed part) of the top gate electrode 412 is disposed at the other end of the inter-electrode connecting part and electrically connected thereto.

According to the field effect transistor according to the present embodiment, since the laminated structure from the buffer layer to the top gate side barrier layer can be laminated on the semiconductor substrate by a series of crystal growth, two channel layers (the top gate side channel layer and the back gate side channel layer) can be grown while taking over the lattice order of the semiconductor substrate, and the high quality of both channel layers, that is, high mobility can be realized. Thus, a higher current driving capability can be obtained, and high-frequency characteristics can be improved.

Further, since a wafer sticking method is not used, it is not necessary to prepare a sacrificial InP substrate, and the manufacturing cost can be suppressed.

In the field effect transistor according to the present embodiment, either one of the first barrier layer 404 and the third barrier layer 408 may be a semiconductor layer, and the other may be an insulating film such as an oxide film. The field effect transistor having this configuration may be manufactured by, for example, a wafer sticking technique.

For example, the buffer layer 402 and the back gate electrode 403 are formed on the semiconductor substrate 401, and then the first barrier layer 404 is deposited. Here, an oxide or a nitride such as SiN, SiO₂, SiON, Al₂O₃, HfO₂, and TiO₂, or a laminated film thereof is used for the first barrier layer 404.

On the other hand, the buffer layer, the third barrier layer (top gate side barrier layer) 408 made up of a semiconductor layer including the δ-doped layer 421, the top gate side channel layer 407, the second barrier layer 406 including the δ-doped layer 415, and the back gate side channel layer 405 are laminated in order on the sacrificial InP substrate, by crystal growth by an organometallic vapor phase growing method or a molecular beam epitaxy method.

Subsequently, as in the first embodiment, after the sacrificial substrate and the semi-insulating InP substrate for the device are stuck together, the sacrificial substrate and the buffer layer are removed, and a laminated structure from the semiconductor substrate 401 to the top gate side barrier layer 408 is manufactured. Thereafter, the first ohmic cap layer 409, the second ohmic cap layer 410, the source electrode 411, the drain electrode 413, the cap recess 414, the inter-electrode connecting part, and the top gate electrode 412 are formed.

Thus, two channel layers (the top gate side channel layer and the back gate side channel layer) can be grown on the sacrificial substrate while taking over the lattice order of the semiconductor substrate by a series of crystal growth. As a result, in the laminated structure on the semi-insulating InP substrate for a device after the sticking process, the quality of both channel layers, that is, the mobility, can be improved.

In the present embodiment, a recess region may be formed around the back gate electrode, as in the second embodiment.

In the present embodiment, the second channel layer (top gate side channel layer) and the first channel layer (back gate side channel layer) may be formed of different materials as in the third embodiment.

In the present embodiment, the first ohmic cap layer and the second ohmic cap layer may be disposed on the second channel layer, respectively, as in the first embodiment. In this configuration, the source electrode and the drain electrode form an ohmic contact with the second channel layer via the first ohmic cap layer and the second ohmic cap layer, respectively.

In the present embodiment, the first barrier layer, the second barrier layer and the third barrier layer may be made of different materials from each other (semiconductors).

### Fifth Embodiment

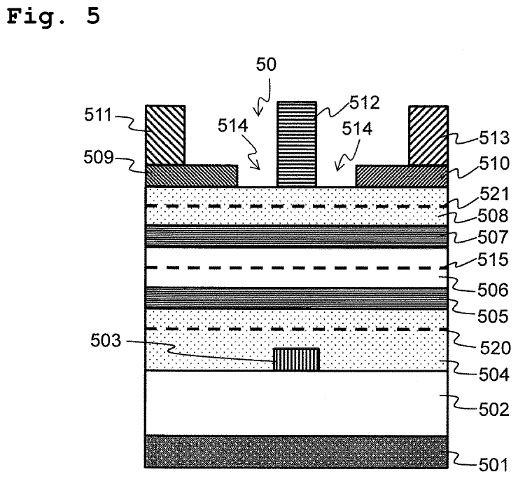

Next, a field effect transistor according to a fifth embodiment of the present invention will be described with reference to FIG. 5.

### Configuration of Field Effect Transistor

As shown in FIG. 5, a field effect transistor 50 according to the present embodiment includes, in order, a semiconductor substrate 501, a buffer layer 502, a first barrier layer (back gate side barrier layer) 504, a first channel layer (back gate side channel layer) 505, a second barrier layer 506, a second channel layer (top gate side channel layer) 507, and a third barrier layer (top gate side barrier layer) 508. A back gate electrode 503 is provided in the first barrier layer (back gate side barrier layer) 504.

The second barrier layer 506 is made of a semiconductor such as InAlAs, and is made of a material substantially lattice-matched with the semiconductor substrate, like the buffer layer. The other components are the same as those of the fourth embodiment.

In general, the buffer layer is introduced for the purpose of forming a high-quality channel layer with extremely small lattice distortion. Therefore, in the present embodiment, by introducing a material similar to that of the buffer layer as the second barrier layer 506, both or one of the back gate side channel layer 505 and the top gate side channel layer 507 can be made high in quality, i.e., high in mobility.

As described above, the material which is “substantially lattice-matched” with the semiconductor substrate is a material having a lattice constant within a range in which crystal quality does not deteriorate due to dislocation or defect when the crystal growth is performed on the semiconductor substrate.

For example, when a device is manufactured by a wafer sticking method using a sacrificial InP substrate, after the top gate side barrier layer 508 and the top gate side channel layer 507 are sequentially formed on the sacrificial substrate, the second barrier layer 506 made of a material similar to that of a buffer layer is formed, and subsequently, the back gate side channel layer 505 is grown.

This makes it possible to improve the quality of the back gate side channel layer 505.

Alternatively, when the respective layers are sequentially grown on the substrate by a series of crystal growth, after the laminated structure from the buffer layer 502 to the back gate side channel layer 505 is formed, the second barrier layer 506 made of the same material as the buffer layer is formed, and the top gate side channel layer 507 is subsequently grown.

This makes it possible to improve the quality of the top gate side channel layer 507.

Further, in the field effect transistor 50 according to the present embodiment, the laminated structure from the substrate 501 to the top gate side barrier layer 508 can be manufactured by the following method.

First, an InP sacrificial substrate is prepared for growth of the back gate side channel layer 505, and a buffer layer (including the second barrier layer 506) and the back gate side channel layer 505 are crystal-grown on the sacrificial substrate by an organometallic vapor phase growth method or a molecular beam epitaxy method.

On the other hand, the buffer layer 502, the back gate electrode 503, and the back gate side barrier layer 504 including the δ-doped layer 520 are formed on the semi-insulating InP substrate 501 for a device.

Next, the surface of the back gate side channel layer 505 on the sacrificial substrate and the surface of the back gate side barrier layer 504 on the semi-insulating InP substrate 501 for the device are stuck to each other to be opposite to each other.

Next, the InP sacrificial substrate and a part of the buffer layer are removed by etching or chemical mechanical polishing, and the second barrier layer 506 is exposed on the surface.

Next, the top gate side channel layer 507 and the top gate side barrier layer 508 are laminated with the exposed second barrier layer 506 as a base.

Thus, since both the back gate side channel layer 505 and the top gate side channel layer 507 are grown on the same material (second barrier layer 506) as the buffer layer, the quality of both of the channel layers can be improved.

Further, in the present embodiment, the δ-doped layer 515 may be formed in the second barrier layer 506. Thus, in addition to the supply of carriers to the top gate side channel layer 507 and the back gate side channel layer 505 by the δ-doped layers 521 and 520 in the top gate side barrier layer 508 and the back gate side barrier layer 504, carriers can be further supplied, and access resistance to the back gate side channel layer 505 can be reduced.

Further, a plurality of δ-doped layers may be formed in the second barrier layer 506 within a range in which the quality of the top gate side channel layer 507 and the back gate side channel layer 505 can be maintained. Thus, since the conduction band in the second barrier layer 506 is locally lowered, carriers can be efficiently injected into the back gate side channel layer 505 with low access resistance. In this way, the access resistance to the back gate side channel layer 505 can be further reduced in the second barrier layer 506 (layer thickness: 100 to 300 nm) thicker than the barrier layer.

According to the field effect transistor according to the present embodiment, the crystal quality of at least one of the first channel layer (back gate side channel layer) and the second channel layer (top gate side channel layer) can be improved, further high current driving capability can be obtained, and high-frequency characteristics can be improved.

Although an example of the InP-based field effect transistor using the InP substrate is shown in the embodiments of the present invention, the embodiments of the present invention are not limited to this, but can be applied to a GaAs-based field effect transistor using a GaAs substrate. In addition, embodiments of the present invention can also be applied to a field effect transistor using other semiconductors such as GaN, InSb, and SiGe.

Although examples of structures, dimensions, materials, and the like of each component in configurations of the field effect transistor, the manufacturing method, and the like are shown in the embodiments of the present invention, the present invention is not limited thereto. Any modifications can be made as long as it exerts the function of the field effect transistor and exhibits an effect.

### Industrial Applicability

Embodiments of the present invention relate to a high-frequency electronic device, and are applicable to high-speed radio communication of the next generation, non-destructive inspection by imaging using terahertz waves, security application by transmission image photographing, material analysis using absorption spectra, and the like.

1.-8. (canceled)

9. A field effect transistor comprising:
on a plane, in order, a source electrode, a first gate electrode, and a drain electrode; and
in a direction perpendicular to the plane, in order:
a first barrier layer;
a second gate electrode disposed in the first barrier layer;
a first channel layer comprising a first semiconductor;
a second barrier layer comprising:
a second semiconductor having an energy gap larger than that of the first channel layer; and
an δ-doped layer;
a second channel layer comprising a third semiconductor having an energy gap smaller than that of the second barrier layer;
a third barrier layer; and
the first gate electrode.

10. The field effect transistor according to claim 9, further comprising:
a first ohmic cap layer disposed between the second channel layer and the source electrode, the first ohmic cap layer comprising a fourth semiconductor configured to form an ohmic contact between the second channel layer and the source electrode; and
a second ohmic cap layer disposed between the second channel layer and the drain electrode, the second ohmic cap layer comprising the fourth semiconductor configured to form the ohmic contact with the second channel layer.

11. The field effect transistor according to claim 9, wherein the first gate electrode and the second gate electrode are electrically connected to each other.

12. The field effect transistor according to claim 9, further comprising a recess region around the second gate electrode.

13. The field effect transistor according to claim 9, wherein the second channel layer and the first channel layer comprise different material compositions from each other.

14. The field effect transistor according to claim 9, wherein the first barrier layer or the third barrier layer comprises a fourth semiconductor having an energy gap larger than that of the first channel layer or the second channel layer.

15. The field effect transistor according to claim 9, wherein the third barrier layer comprises a fourth semiconductor having an energy gap larger than that of the second channel layer.

16. The field effect transistor according to claim 15, further comprising:
a first ohmic cap layer disposed between the third barrier layer and the source electrode, the first ohmic cap layer configured to form an ohmic contact with the third barrier layer; and
a second ohmic cap layer disposed between the third barrier layer and the drain electrode, the second ohmic cap layer configured to form the ohmic contact with the third barrier layer.

17. The field effect transistor according to claim 9, further comprising, on a side of the first barrier layer opposite to a plane on a first channel layer side, in order:
a buffer layer; and
a semiconductor substrate, wherein the second barrier layer is substantially lattice-matched with the semiconductor substrate.

18. A field effect transistor comprising:
a buffer layer disposed on a semiconductor substrate;
a first barrier layer disposed on the buffer layer;
a first gate electrode disposed in the first barrier layer;
a first channel layer comprising a first semiconductor disposed on the first barrier layer;
a second barrier layer disposed on the first channel layer, the second barrier layer comprising:
a second semiconductor having an energy gap larger than that of the first channel layer; and
an δ-doped layer;
a second channel layer disposed on the second barrier layer, the second channel layer comprising a third semiconductor having an energy gap smaller than that of the second barrier layer;
a third barrier layer disposed on the second channel layer; and
a second gate electrode disposed on the third barrier layer.

19. The field effect transistor according to claim 18, further comprising:
a first ohmic cap layer comprising a fourth semiconductor disposed on the second channel layer on a first side of the second gate electrode;
a source electrode disposed on the first ohmic cap layer, wherein the first ohmic cap layer is configured to form an ohmic contact between the second channel layer and the source electrode;
a second ohmic cap layer comprising the fourth semiconductor disposed on the second channel layer on a second side of the second gate electrode opposite the first side; and
a drain electrode disposed on the second ohmic cap layer, wherein the second ohmic cap layer is configured to form the ohmic contact between the second channel layer and the drain electrode.

20. The field effect transistor according to claim 18, wherein the first gate electrode and the second gate electrode are electrically connected to each other.

21. The field effect transistor according to claim 18, further comprising a recess region around the first gate electrode.

22. The field effect transistor according to claim 18, wherein the second channel layer and the first channel layer comprise different material compositions from each other.

23. The field effect transistor according to claim 18, wherein the first barrier layer or the third barrier layer comprises a fourth semiconductor having an energy gap larger than that of the first channel layer or the second channel layer.

24. The field effect transistor according to claim 18, wherein the third barrier layer comprises a fourth semiconductor having an energy gap larger than that of the second channel layer.

25. The field effect transistor according to claim 24, further comprising:
a first ohmic cap layer disposed between the third barrier layer and a source electrode disposed on a first side of the second gate electrode, wherein the first ohmic cap layer is configured to form an ohmic contact with the third barrier layer; and
a second ohmic cap layer disposed between the third barrier layer and a drain electrode disposed on a second side of the second gate electrode opposite the first side, wherein the second ohmic cap layer is configured to form the ohmic contact with the third barrier layer.

26. The field effect transistor according to claim 18, wherein the second barrier layer is substantially lattice-matched with the semiconductor substrate.
